(19) United States
(12) Patent Application Publication
(10) Pub. No.: US 2026/0303991 A1
(43) Pub. Date: Oct. 1, 2026

(54) IMAGE SENSOR, OPERATING METHOD OF IMAGE SENSOR AND CAMERA MODULE INCLUDING IMAGE SENSOR

(71) Applicant: Samsung Electronics Co., Ltd., Suwon-si (KR)

(72) Inventors: Jinsuk HUH, Suwon-si (KR); Junoh KIM, Suwon-si (KR); JUNG BIN YUN, Suwon-si (KR)

(21) Appl. No.: 19/576,265

(22) Filed: Mar. 24, 2026

(30) Foreign Application Priority Data
Mar. 31, 2025 (KR) 10-2025-0041690

(51) Int. Cl. H04N 25/68; H04N 25/65

(52) U.S. Cl. CPC H04N 25/68; H04N 25/65

(57) ABSTRACT

A method of operating an image sensor includes alternately supplying a first voltage and a second voltage to a first source/drain terminal of a source-follower transistor, wherein a gate electrode of the source-follower transistor is connected to a first floating diffusion node. The alternately supplying of the first voltage and the second voltage includes supplying the second voltage to the first source/drain terminal, resetting the first floating diffusion node to a reset voltage, blocking the supplying of the second voltage and supplying the first voltage to the first source/drain terminal, transmitting a first signal of a first photodiode to the first floating diffusion node, sensing a first signal of the first floating diffusion node through the source-follower transistor, and blocking the supplying of the first voltage to the first source/drain terminal and supplying the second voltage to the first source/drain terminal.

### CROSS-REFERENCE TO RELATED APPLICATIONS

This application claims priority under 35 U.S.C. § 119 to Korean Patent Application No. 10-2025-0041690 filed on Mar. 31, 2025, in the Korean Intellectual Property Office, the disclosures of which are incorporated by reference herein in their entireties.

### BACKGROUND

The present disclosure relates to an electronic device, and more particularly, to an image sensor that generates image data having improved image quality, an operation method of the image sensor, and a camera module including the image sensor.

An image sensor may include a plurality of pixels, and generate image data using the plurality of pixels. The image data generated by the image sensor may include various noises and distortions.

At least some of the noises and distortions generated by the image sensor may be caused by electrons being trapped in a transistor. In order to correct the noises and distortions caused by electrons trapped in the transistor, a method of adding a logic circuit or increasing a size of the transistor can be used. However, the method of adding the logic circuit or increasing the size of the transistor may have the disadvantage of increasing a size of the image sensor.

### SUMMARY

Embodiments of the present disclosure provide an image sensor that correct noises and distortions generated by electrons trapped in a transistor while suppressing an increase in a size of the image sensor, an operating method of the image sensor, and a camera module including the image sensor.

According to an aspect of the present disclosure, a method of operating an image sensor includes alternately supplying a first voltage and a second voltage to a first source/drain terminal of a source-follower transistor, wherein a gate electrode of the source-follower transistor is connected to a first floating diffusion node. The alternately supplying of the first voltage and the second voltage includes supplying the second voltage to the first source/drain terminal of the source-follower transistor, resetting the first floating diffusion node to a reset voltage, blocking the supplying of the second voltage and supplying the first voltage to the first source/drain terminal of the source-follower transistor, transmitting a first signal of a first photodiode to the first floating diffusion node, sensing a first signal of the first floating diffusion node through the source-follower transistor, and blocking the supplying of the first voltage to the first source/drain terminal of the source-follower transistor and supplying the second voltage to the first source/drain terminal of the source-follower transistor.

According to an aspect of the present disclosure, a method of operating an image sensor includes turning off a select-gate transistor connecting a source-follower transistor to a current source, wherein the source-follower transistor is connected to a floating diffusion node, during a time when the select-gate transistor is turned off, trapping electrons in trap sites of the source-follower transistor, and resetting the floating diffusion node to a reset voltage, turning on the select-gate transistor, and during a time when the select-gate transistor is turned on, transmitting a signal of a photodiode to the floating diffusion node, and sensing a signal of the floating diffusion node through the source-follower transistor.

According to an aspect of the present disclosure, an image sensor includes a photodiode, a transfer gate transistor connected between the photodiode and a floating diffusion node, a source-follower transistor including a first source/drain terminal, a second source/drain terminal, and a gate electrode coupled to the floating diffusion node, a first switch transistor selectively connecting the first source/drain terminal of the source-follower transistor to a first voltage node supplying a first voltage, a second switch transistor selectively connecting the first source/drain terminal of the source-follower transistor to a second voltage node supplying a second voltage, and a select-gate transistor selectively connecting the second source/drain terminal of the source-follower transistor to a current source. During a non-readout time period in which the select-gate transistor is turned off, the first switch transistor is turned off, and the second switch transistor is turned on to supply the second voltage to a first/source drain terminal of the source-follower transistor and trap electrons in trap sites of the source-follower transistor using the second voltage. During a readout time period in which the select-gate transistor is turned on, the second switch transistor is turned off, and the first switch transistor is turned on to supply the first voltage to the first/source drain terminal of the source-follower transistor for sensing a signal of the floating diffusion node.

### BRIEF DESCRIPTION OF THE FIGURES

The above and other objects and features of the present disclosure will become apparent by describing in detail embodiments thereof with reference to the accompanying drawings.

FIG. 1 shows an image sensor according to an embodiment of the present disclosure.

FIG. 2 shows a pixel, a current source connected to the pixel, and an analog-to-digital converter connected to the pixel according to an embodiment of the present disclosure.

FIG. 3 shows an example of signals applied to the pixel of FIG. 2.

FIG. 4 shows an example where a second switch transistor supplies a second voltage to a source follower transistor.

FIG. 5 shows an example in which a first switch transistor supplies a first voltage to a source follower transistor.

FIG. 6 shows a pixel, a current source connected to the pixel, and an analog-to-digital converter connected to the pixel according to another embodiment of the present disclosure.

FIG. 7 shows a pixel, a current source connected to the pixel, and an analog-to-digital converter connected to the pixel according to still another embodiment of the present disclosure.

FIG. 8 shows a pixel, a current source connected to the pixel, and an analog-to-digital converter connected to the pixel according to yet another embodiment of the present disclosure.

FIG. 9 illustrates a method of operating an image sensor according to an embodiment of the present disclosure.

FIG. 10 is a block diagram of an electronic device including a multi-camera module.

FIG. 11 is a detailed block diagram of the camera module of FIG. 10.

### DETAILED DESCRIPTION

Below, embodiments of the present disclosure will be described in detail and clearly to such an extent that a person of ordinary skill in the art easily implements the invention.

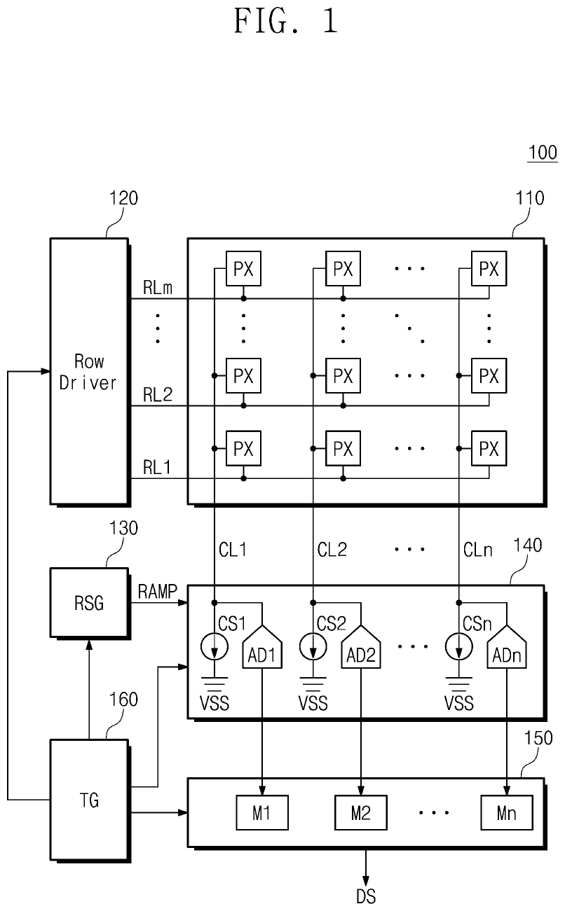

FIG. 1 shows an image sensor 100 according to an embodiment of the present disclosure. Referring to FIG. 1, the image sensor 100 may include a pixel array 110, a row driver 120, a ramp signal generator 130 (RSG), an analog-to-digital conversion circuit 140, a memory circuit 150, and a timing generator 160 (TG).

The pixel array 110 may include a plurality of pixels PX arranged in a matrix along rows and columns. Each of the plurality of pixels PX may include photo detectors. For example, the photo detectors may include a photodiode, a phototransistor, a photogate, a pinned photodiode, or the like. Each of the plurality of pixels PX may sense light using a photo detector and convert an amount of the sensed light into an electrical signal, for example, a voltage or a current.

A color filter array (CFA) and a lens may be stacked on the pixel array 110. The color filter array may include filters of red (R), green (G) and blue (B). Two or more different color filters may be disposed in the plurality of pixels PX. For example, at least one blue color filter, at least one red color filter, and at least two green color filter may be disposed in the plurality of pixels PX.

The row driver 120 may be connected to the rows of the pixels PX of the pixel array 110 through the first to m-th row lines RL1 to RLm (m is a positive integer). The row driver 120 may decode the address and/or control signal generated by the timing generator 160 to sequentially select the first to m-th row lines RL1 to RLm of the pixel array 110 and drive the selected row line to a particular voltage. For example, the row driver 120 may drive the selected row line to a voltage suitable for sensing light.

Each of the first to m-th row lines RL1 to RLm connected to the rows of pixels PX may include two or more lines. The two or more lines may carry various signals including, for example, a signal for selecting (or activating) photo detectors of a pixel, a signal for resetting a floating diffusion node, a signal for choosing a column line, a signal for adjusting a conversion gain (CG), and/or the like, respectively.

The ramp signal generator 130 may generate a ramp signal RAMP. The ramp signal generator 130 may operate under a control of the timing generator 160. For example, the ramp signal generator 130 may operate under a control of a control signal, such as a ramp enable signal, a mode signal, and/or the like. In response to the ramp enable signal being activated, the ramp signal generator 130 may generate the ramp signal RAMP having a slope that is set based on the mode signal. For example, the ramp signal generator 130 may generate the ramp signal RAMP that continuously decreases or increases from an initial level over time.

The analog-to-digital conversion circuit 140 may be connected to columns of the pixels PX of the pixel array 110 through first to n-th column lines CL1 to CLn (n is a positive integer), respectively. The analog-to-digital conversion circuit 140 may include first to n-th current sources CS1 to CSn and first to n-th analog-to-digital converters AD1 to ADn connected to the first to n-th column lines CL1 to CLn, respectively. The first to n-th current sources CS1 to CSn may be respectively connected between a ground node to which a ground voltage VSS is applied and the first to n-th column lines CL1 to CLn. The first to n-th current sources CS1 to CSn may be designed to flow constant currents through the first to n-th column lines CL1 to CLn, respectively. While the first to n-th current sources CS1 to CSn flow constant currents, pixels of a selected row line of the first to m-th row lines RL1 to RLm may output pixel voltages corresponding to the intensity of incident light to the first to n-th column lines CL1 to CLn.

The first to n-th analog-to-digital converters AD1 to ADn may commonly receive the ramp signal RAMP from the ramp signal generator 130. The first to n-th analog-to-digital converters AD1 to ADn may compare voltages of the first to n-th column lines CL1 to CLn with the ramp signal RAMP. The ramp signal RAMP is a signal that decreases (or increases) at a constant rate over time. Each of the first to n-th analog-to-digital converters AD1 to ADn may latch a count value until the ramp signal RAMP becomes smaller (or greater) than a voltage of a corresponding one of the first to n-th column lines CL1 to CLn, and convert the latched count value into a digital value and output the digital value.

That is, the first to n-th analog-to-digital converters AD1 to ADn may output the digital values corresponding to magnitudes (or amounts) of voltages (or currents) output from the pixels PX to the first to n-th column lines CL1 to CLn. As an example, the first to n-th analog-to-digital converters AD1 to ADn may output the digital values of initial voltages of the first to n-th column lines CL1 to CLn, and the digital values of pixel voltages corresponding to the intensity of the incident light.

The memory circuit 150 may include first to n-th memories M1 to Mn respectively corresponding to the first to n-th analog-to-digital converters AD1 to ADn. The first to n-th memories M1 to Mn may store the digital values received from the first to n-th analog-to-digital converters AD1 to ADn, and output the stored digital values as a digital signal DS. For example, the first to n-th memories M1 to Mn may output a difference between the digital values of the initial voltages and the digital values of the pixel voltages as the digital signal DS.

The timing generator 160 (TG) may control timings at which the image sensor 100 operates. The timing generator 160 may control timings at which the row driver 120 sequentially selects the first to m-th row lines RL1 to RLm, and control the timings at which signals are transmitted through two or more lines included in the selected row line of the first to m-th row lines RL1 to RLm.

The timing generator 160 may control timings at which the ramp signal generator 130 generates the ramp signal RAMP and initializes the ramp signal RAMP. The timing generator 160 may control timings at which the first to n-th analog-to-digital converters AD1 to ADn start counting and comparing and timings at which the first to n-th analog-to-digital converters AD1 to ADn are initialized.

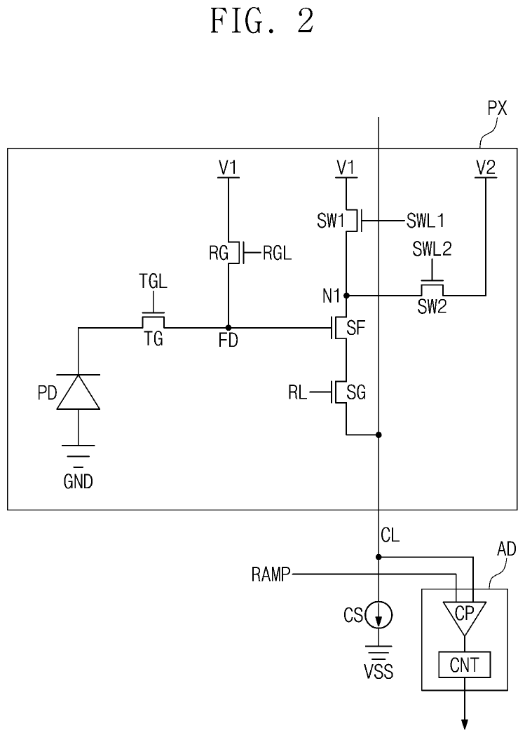

FIG. 2 shows a pixel PX, a current source CS connected to the pixel PX, and an analog-to-digital converter AD connected to the pixel PX according to an embodiment of the present disclosure. Referring to FIGS. 1 and 2, the pixel PX may include a photodiode PD, a transfer gate transistor TG, a source follower transistor SF (i.e., a source-follower transistor), a select gate transistor SG (i.e., a select-gate transistor), a first switch transistor SW1, a second switch transistor SW2, and a reset gate transistor RG (i.e., a reset-gate transistor).

The photodiode PD may be connected between the ground node to which the ground voltage GND is applied and the transfer gate transistor TG. The transfer gate transistor TG may include a gate electrode connected to a transfer gate line TGL, a first node connected to the photodiode PD, and a second node connected to a floating diffusion node FD. Hereinafter, a node of a transistor refers to a source/drain terminal of the transistor. For example, the first node of the source follower transistor SF and the second node thereof refer to a first source/drain terminal of the source follower transistor SF and a second source/drain terminal thereof, respectively.

The source follower transistor SF may include a gate electrode coupled to the floating diffusion node FD, a first node coupled to a first node N1, and a second node coupled to a first node of the select gate transistor SG.

The select gate transistor SG may include a gate electrode connected to a corresponding row line RL of the first to m-th row lines RL1 to RLm, a first node connected to the second node of the source follower transistor SF, and a second node connected to a corresponding column line CL of the first to n-th column lines CL1 to CLn.

The first switch transistor SW1 may include a gate electrode connected to a first switch line SWL1, a first node connected to a first voltage node to which a first voltage V1 is applied, and a second node connected to the first node N1.

The second switch transistor SW2 may include a gate electrode connected to a second switch line SWL2, a first node connected to a second voltage node to which a second voltage V2 is applied, and a second node connected to the first node N1.

As an example, the second voltage V2 may be lower than the first voltage V1. The first voltage V1 and the second voltage V2 may be positive voltages. The second voltage V2 may be lower than a voltage of the floating diffusion node FD. In an embodiment, the second voltage V2 may be lower than a reset voltage of the floating diffusion node FD. The reset voltage of the floating diffusion node FD may be the first voltage V1 supplied through the reset gate transistor RG. For example, the first voltage V1 may be 2V to 3V, and the second voltage V2 may be 1V. The present disclosure is not limited thereto. The reset voltage of the floating diffusion node FD may be a voltage different from the first voltage V1. For example, the reset voltage may be a voltage between the first voltage V1 and the second voltage V2.

The reset gate transistor RG may include a gate electrode connected to a reset gate line RGL, a first node connected to the first voltage node to which the first voltage V1 is applied, and a second node connected to the floating diffusion node FD.

The current source CS may be connected between the ground node to which the ground voltage GND is applied and the column line CL. The current source CS may be implemented as a current mirror that operates as a current sink. The current source CS may include at least one transistor provided between the ground node and the column line CL. To flow a constant current through the column line CL, the at least one transistor may be designed to operate in a saturated state.

The analog-to-digital converter AD may include a comparator CP and a counter CNT. The comparator CP may compare the ramp signal RAMP with a voltage of the column line CL, for example, an initial voltage or a pixel voltage. The counter CNT may perform counting from a predetermined timing until the output of the comparator CP changes, for example, until the ramp signal RAMP becomes greater or smaller than the voltage of the column line CL. The count value obtained from the initial voltage of the column line CL may be an initial value. The difference between the count value obtained from the pixel voltage of the column line CL and the initial value may be a pixel value. For example, the pixel value may be a value obtained by subtracting the initial value from the count value of the pixel voltage.

In a process in which the pixel PX converts the intensity of incident light into a pixel voltage, first, the reset gate transistor RG is turned on, and the floating diffusion node FD may be initialized to the first voltage V1 which is supplied as a reset voltage of the floating diffusion node FD. The transfer gate transistor TG may dump electrons generated by the photodiode PD into the floating diffusion node FD. For example, after resetting the floating diffusion node FD to the first voltage V1, the transfer gate transistor TG may dump electrons generated by the photodiode PD into the floating diffusion node FD. With the electrons being dumped, the voltage of the floating diffusion node FD may decrease from the first voltage V1 to a voltage lower than the first voltage V1. The source follower transistor SF may output the pixel voltage corresponding to a change in the voltage of the floating diffusion node FD to the column line CL through the select gate transistor SG.

As the intensity of light incident on the pixel PX increases, the number of electrons generated by the photodiode PD may increase. As the number of electrons dumped to the floating diffusion node FD increases, an amount of a change (i.e., decrease) in the voltage of the floating diffusion node FD may increase.

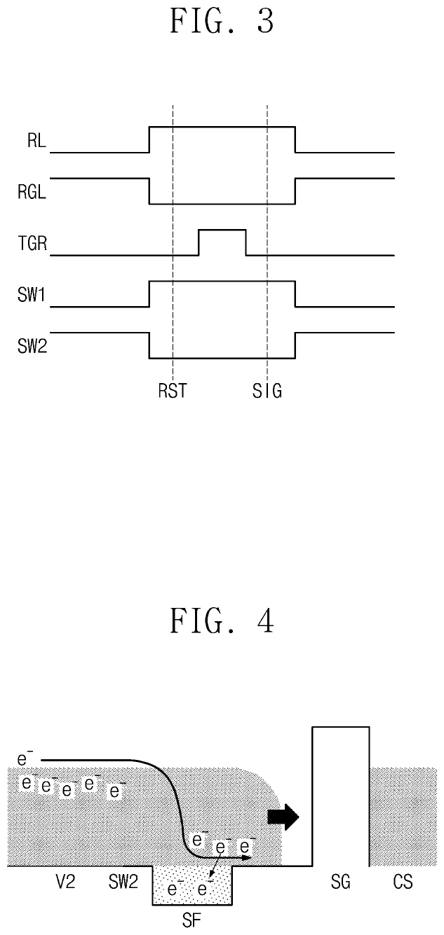

FIG. 3 shows an example of signals applied to the pixel PX of FIG. 2. Referring to FIGS. 2 and 3, during a time period in which the readout is not performed in the pixel PX (i.e., during a non-readout time interval in which the select gate transistor SG is turned off), the first switch transistor SW1 may be turned off, and the second switch transistor SW2 may be turned on. The second switch transistor SW2 may supply the second voltage V2 to the source follower transistor SF. In the time period in which the readout is not performed, the select gate transistor SG, the transfer gate TG, and the first switch transistor SW1 are turned off, and the reset gate transistor RG and the second switch transistor SW2 are turned on.

FIG. 4 illustrates an example in which the second switch transistor SW2 supplies the second voltage V2 to the first node of the source follower transistor SF. Illustratively, an example of the potential of electrons ‘e’ is shown in FIG. 4. Referring to FIGS. 2, 3, and 4, during a time period in which the readout is not performed, the select gate transistor SG may be in a turn-off state. That is, the select gate transistor SG acts as a potential barrier to the electrons ‘e’, and can block the supply of electrons from the current source CS to the source follower transistor SF.

A gate electrode of the source follower transistor SF may be connected to the floating diffusion node FD. The voltage of the gate of the floating diffusion node FD may be a first voltage V1 or a positive voltage having a level similar to the first voltage V1. Accordingly, the potential of the gate electrode of the source follower transistor SF may be relatively lower than the first voltage V1.

The second voltage V2 may be supplied to the source follower transistor SF through the turned-on second switch transistor SW2. The electrons ‘e’ supplied from the power supply node of the second voltage V2 may be trapped in trap sites of the source follower transistor SF. For example, the electrons ‘e’ may be trapped in trap sites at a gate insulating film of the source follower transistor SF.

Referring again to FIGS. 2 and 3, during a time period in which the readout is performed in the pixel PX, the first switch transistor SW1 may be turned on, and the second switch transistor SW2 may be turned off. The first switch transistor SW1 may supply the first voltage V1 to the source follower transistor SF.

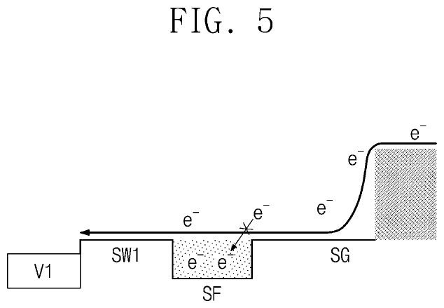

FIG. 5 illustrates an example in which the first switch transistor SW1 supplies the first voltage V1 to the source follower transistor SF. Illustratively, an example of the potential of electrons ‘e’ is shown in FIG. 5. Referring to FIGS. 2, 3, and 5, during a time period in which the readout is performed, the select gate transistor SG may be in a turned-on state. That is, the select gate transistor SG may supply the electrons ‘e’ generated by the current source CS to the source follower transistor SF.

The length of the time period in which the readout is performed may be shorter than the time in which the electrons ‘e’ trapped in trap sites of the source follower transistor SF escape. Therefore, during the time period in which the readout is performed, the electrons ‘e’ trapped in trap sites of the source follower transistor SF by the second voltage V2 and the second switch transistor SW2 may maintain a trapped state. Since the electrons ‘e’ are trapped in trap sites of the source follower transistor SF, the electrons ‘e’ transferred from the current source CS may not be trapped in trap sites of the source follower transistor SF. Therefore, during the time period in which the readout is performed, the threshold voltage of the source follower transistor SF may be uniformly maintained, and the current of the current source CS may also be uniformly maintained. That is, noises or distortions may be suppressed from occurring in the image data due to a phenomenon in which the electrons ‘e’ are trapped in trap sites of the source follower transistor SF.

Illustratively, the row line RL may maintain a low level during the time period in which the readout is not performed, and maintain a high level during the time period in which the readout is performed. That is, the select gate transistor SG may be turned off during the time period in which the readout is not performed, and may be turned on during the time period in which the readout is performed.

The reset gate line RGL may maintain a high level during the time period in which the readout is not performed, and maintain a low level during the time period in which the readout is performed. That is, the reset gate transistor RG may be turned on during the time period in which the readout is not performed, and may be turned off during the time period during which the readout is performed.

During the time period in which the readout is performed, a reset operation RST and a signal sensing operation SIG may be performed at the pixel. In the reset operation RST, the voltage of the floating diffusion node FD reset by the reset gate transistor RG during the time period in which the readout is not performed may be output to the column line CL by the source follower transistor SF and the select gate transistor SG.

Thereafter, in the signal sensing operation SIG, the transfer gate line TGL transitions from the low level to the high level and the transfer gate transistor TG is turned on, the electrons generated by the photodiode PD are transferred to the floating diffusion node FD, and the voltage of the floating diffusion node FD may change. Thereafter, the transfer gate line TGL may transition from the high level to the low level, and the transfer gate transistor TG may be turned off.

The voltage of the floating diffusion node FD changed by the photodiode PD in the signal sensing operation SIG may be output to the column line CL by the source follower transistor SF and the select gate transistor SG.

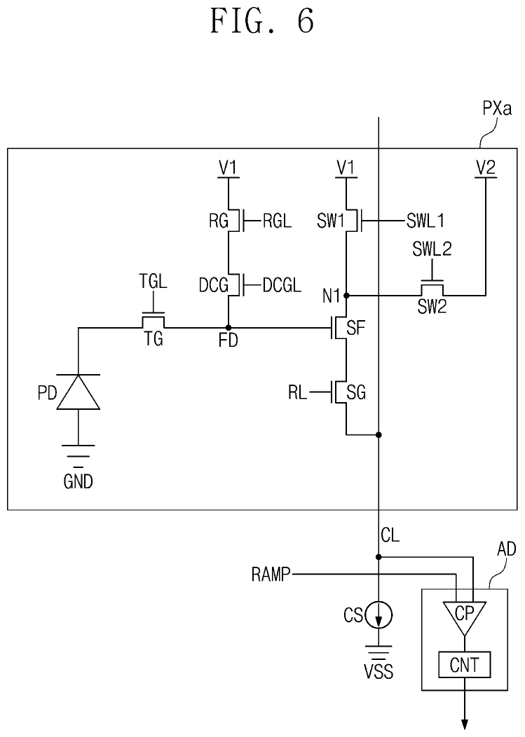

FIG. 6 shows a pixel PXa, a current source CS connected to the pixel PXa, and an analog-to-digital converter AD connected to the pixel PXa according to another embodiment of the present disclosure. Referring to FIGS. 1 and 6, the pixel PXa may include the photodiode PD, the transfer gate transistor TG, the source follower transistor SF, the select gate transistor SG, the first switch transistor SW1, the second switch transistor SW2, the reset gate transistor RG, and a dual conversion gain transistor DCG. Compared with the pixel PX of FIG. 2, the pixel PXa of FIG. 6 may further include the dual conversion gain transistor DCG.

The dual conversion gain transistor DCG may include a gate electrode coupled to a dual conversion gain line DCGL, a first node coupled to the second node of the reset gate transistor RG, and a second node coupled to the floating diffusion node FD. The dual conversion gain transistor DCG may be used to adjust the capacitance of the floating diffusion node FD.

In some example embodiment, as described in FIG. 3, in a first time period in which a first readout is performed, the reset gate transistor RG and the dual conversion gain transistor DCG may maintain a turn-off state. In the first time period in which the first readout is performed, the reset operation RST and the signal sensing operation SIG may be performed as described with reference to FIG. 3.

Thereafter, in a second time period in which a second readout is performed subsequent to the first time period, the dual conversion gain transistor DCG may be turned on to increase the capacitance of the floating diffusion node FD. When the dual conversion gain transistor DCG is turned on, the capacitance of the floating diffusion node FD may increase. For example, two capacitive elements may be selectively coupled to the floating diffusion node FD in parallel. The two capacitive elements may include an intrinsic capacitance of the floating diffusion node FD (e.g., a diffusion junction or gate overlap) and an extra capacitance that can be selectively switched in by the dual conversion gain transistor DCG. When the two capacitive elements are coupled in parallel to the floating diffusion node FD, the capacitance of the floating diffusion node FD increases. Thereafter, the signal sensing operation SIG may be performed once more. In the second time period in which the second readout is performed, after the signal sensing operation SIG is performed, the floating diffusion node FD may be reset through the reset gate transistor RG and the dual conversion gain transistor DCG. Then, in the second time period in which the readout is performed, the reset operation RST may be performed once more. In an embodiment, correlated double sampling may include the first readout and the second readout to cancel a reset noise which is a thermal noise left on the floating diffusion node FD after the reset gate transistor RG is turned off.

In some example embodiment, during a time period in which the readout is not performed, the first switch transistor SW1 may be turned off, and the second switch transistor SW2 may be turned on. The first switch transistor SW1 may be turned on and the second switch transistor SW2 may be turned off while the reset operation RST and the signal sensing operation SIG are performed in the first time period in which the first readout is performed, and the signal sensing operation SIG and the reset operation RSG are performed in the second time period in which the second readout is performed.

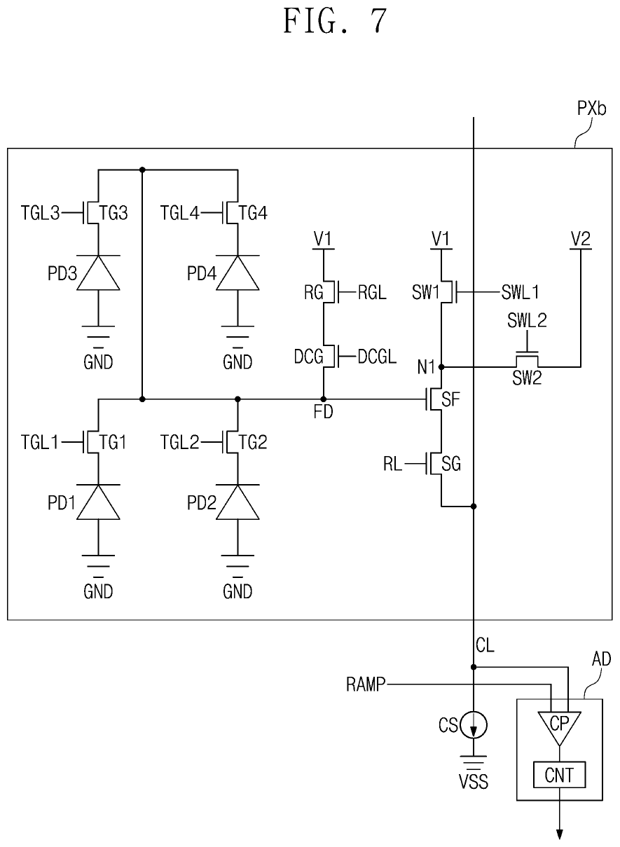

FIG. 7 shows a pixel PXb, a current source CS connected to the pixel PXb, and an analog-to-digital converter AD connected to the pixel PXb according to still another embodiment of the present disclosure. Referring to FIGS. 1 and 7, the pixel PXb may include a first photodiode PD1, a first transfer gate transistor TG1, a second photodiode PD2, a second transfer gate transistor TG2, a third photodiode PD3, a third transfer gate transistor TG3, a fourth photodiode PD4, a fourth transfer gate transistor TG4, the source follower transistor SF, the select gate transistor SG, the first switch transistor SW1, the second switch transistor SW2, the reset gate transistor RG, and the dual conversion gain transistor DCG.

Compared with the pixel PX of FIG. 6, the pixel PXb of FIG. 7 may include the first photodiode PD1, the first transfer gate transistor TG1, the second photodiode PD2, the second transfer gate transistor TG2, the third photodiode PD3, the third transfer gate transistor TG3, the fourth photodiode PD4, and the fourth transfer gate transistor TG4.

The first transfer gate transistor TG1 may transfer electrons generated by the first photodiode PD1 to the floating diffusion node FD in response to a signal of the first transfer gate line TGL1. The second transfer gate transistor TG2 may transfer electrons generated by the second photodiode PD2 to the floating diffusion node FD in response to a signal of the second transfer gate line TGL2.

The third transfer gate transistor TG3 may transfer electrons generated by the third photodiode PD3 to the floating diffusion node FD in response to a signal of the third transfer gate line TGL3. The fourth transfer gate transistor TG4 may transfer electrons generated by the fourth photodiode PD4 to the floating diffusion node FD in response to a signal of the fourth transfer gate line TGL4.

In some example embodiment, in the time period in which the readout is performed, in the signal sensing operation SIG, the first transfer gate transistor TG1, the second transfer gate transistor TG2, the third transfer gate transistor TG3, and the fourth transfer gate transistor TG4 may be simultaneously turned on. When the first to fourth transfer gate transistor TG1 to TG4 turn on simultaneously, the floating diffusion node FD may have an accumulated signal of electrons generated by the first to fourth photodiodes PD1 to PD4. In some example embodiment, in the time period in which the readout is performed, before the first transfer gate transistor TG1, the second transfer gate transistor TG2, the third transfer gate transistor TG3, and the fourth transfer gate transistor TG4 are simultaneously turned on, the floating diffusion node FD may be reset to the first voltage V1.

In some example embodiment, in the time period in which the readout is performed, in the signal sensing period SIG, the first transfer gate transistor TG1, the second transfer gate transistor TG2, the third transfer gate transistor TG3, and the fourth transfer gate transistor TG4 may be sequentially turned on. For example, after the reset operation RST and the signal sensing operation SIG are performed on the first transfer gate transistor TG1, the floating diffusion node FD may be reset to the first voltage V1. Thereafter, after the reset operation RST and the signal sensing operation SIG are performed on the second transfer gate transistor TG2, the floating diffusion node FD may be reset to the first voltage V1. Thereafter, after the reset operation RST and the signal sensing period SIG are performed on the third transfer gate transistor TG3, the floating diffusion node FD may be reset to the first voltage V1. Then, a reset operation RST and a signal sensing operation SIG may be performed on the fourth transfer gate transistor TG4.

In some example embodiment, in the time period in which the readout is performed, a first group of the first transfer gate transistor TG1, the second transfer gate transistor TG2, the third transfer gate transistor TG3, and the fourth transfer gate transistor TG4 may be turned on at the same time, a second group of the first transfer gate transistor TG1, the second transfer gate transistor TG2, the third transfer gate transistor TG3, and the fourth transfer gate transistor TG4 may be turned on simultaneously, and the first group and the second group may sequentially be turned on. After the reset operation RST and the signal sensing operation SIG are performed on the first group, the floating diffusion node FD may be reset to the first voltage V1. Thereafter, a reset operation RST and a signal sensing operation SIG may be performed on the second group. In an embodiment, the first group and the second group may be selectively connected to the floating diffusion node FD.

In some example embodiment, in a first time period in which a first readout is performed, the reset operation RST and the signal sensing operation SIG may be performed while the dual conversion gain transistor DCG is turned off, and in a second time period in which a second readout is performed, the signal sensing operation SIG and the reset operation RSG may be performed while the dual conversion gain transistor DCG is turned on. In some example embodiment, during the time period in which the readout is not performed, the first switch transistor SW1 may be turned off, and the second switch transistor SW2 may be turned on. The first switch transistor SW1 may be turned on and the second switch transistor SW2 may be turned off while the reset operation RST and the signal sensing operation SIG are performed in the first time period in which the first readout is performed, and the signal sensing operation SIG and the reset operation RSG are performed in the second time period in which the second readout is performed.

As described with reference to FIG. 2, the dual conversion gain transistor DCG may be omitted. In some example embodiment, during the time period in which the readout is not performed, the first switch transistor SW1 may be turned off, and the second switch transistor SW2 may be turned on. While the reset operation RST and the signal sensing operation SIG are performed in the time period in which the readout is performed, the first switch transistor SW1 may be turned on and the second switch transistor SW2 may be turned off.

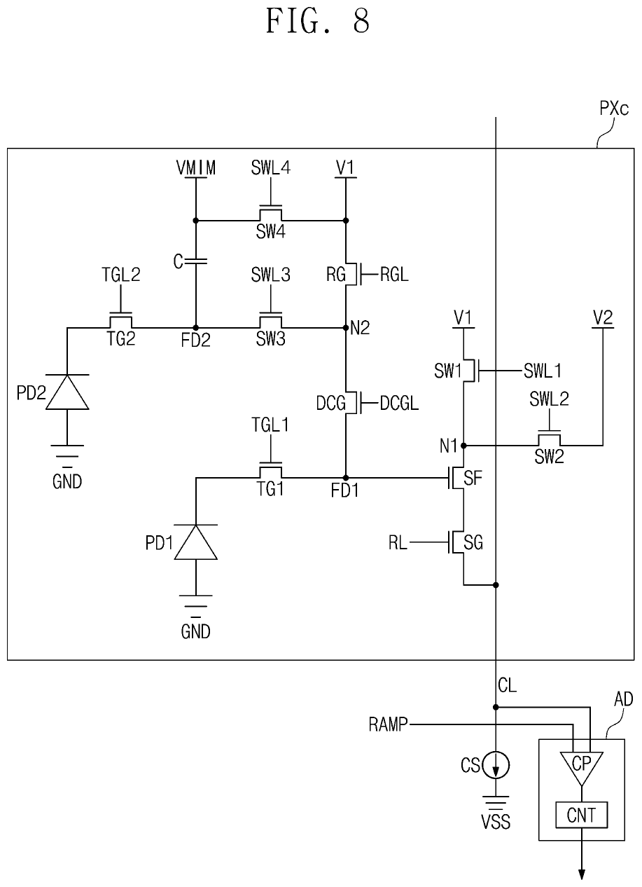

FIG. 8 shows a pixel PXc, a current source CS, and an analog-to-digital converter AD according to yet another embodiment of the present disclosure. Referring to FIG. 8, the pixel PXc may include the first photodiode PD1, the first transfer gate transistor TG1, the second photodiode PD2, the second transfer gate transistor TG2, the source follower transistor SF, the select gate transistor SG, the dual conversion gain transistor DCG, the first switch transistor SW1, the second switch transistor SW2, a third switch transistor SW3, a fourth switch transistor SW4, the reset gate transistor RG, and a capacitor C.

Compared with the pixel PXb of FIG. 6, the pixel PXc of FIG. 8 may include the first transfer gate transistor TG1, the second photodiode PD2, the second transfer gate transistor TG2, the first switch transistor SW1, the second switch transistor SW2, the third switch transistor SW3, the fourth switch transistor SW4, and the capacitor C. In FIG. 8, the first floating diffusion node FD1 may be connected to the gate electrode of the source follower transistor SF, and the second floating diffusion node FD2 may be selectively connected to the first floating diffusion node through the third switch transistor SW3 and the dual conversion gain transistor DCG.

The first photodiode PD1 may be connected between the ground node to which the ground voltage GND is applied and the first transfer gate transistor TG1. The first transfer gate transistor TG1 may include a gate electrode connected to a first transfer gate line TGL1, a first node connected to the first photodiode PD1, and a second node connected to a first floating diffusion node FD1.

The second photodiode PD2 may be connected between the ground node to which the ground voltage GND is applied and the second transfer gate transistor TG2. The second transfer gate transistor TG2 may include a gate electrode connected to a second transfer gate line TGL2, a first node connected to the second photodiode PD2, and a second node connected to a second floating diffusion node FD2.

The source follower transistor SF may include a gate electrode connected to the first floating diffusion node FD1, a first node connected to the first voltage node to which the first voltage V1 is applied, and a second node connected to a first node of the select gate transistor SG.

The select gate transistor SG may include a gate electrode connected to a corresponding row line RL of the first to m-th row lines RL1 to RLm, the first node connected to the second node of the source follower transistor SF, and a second node connected to a corresponding column line CL of the first to n-th column lines CL1 to CLn.

The dual conversion gain transistor DCG may include a gate electrode connected to a dual conversion gain line DCGL, a first node connected to a second node N2 to which a second node of the third switch transistor SW3 and a second node of the reset gate transistor RG are connected, and a second node connected to the first floating diffusion node FD1.

The reset gate transistor RG may include a gate electrode connected to the reset gate line RGL, a first node connected to the first voltage node to which the first voltage V1 is applied and a second node of the fourth switch transistor SW4, and a second node connected to a second node N2 to which the second node of the third switch transistor SW3 and the first node of the dual conversion gain transistor DCG are connected.

The third switch transistor SW3 may include a gate electrode connected to the third switch line SWL3, a first node connected to the second floating diffusion node FD2, and a second node connected to the second node N2 to which the second node of the reset gate transistor RG and the first node of the dual conversion gain transistor DCG are connected.

The capacitor C may include a first node connected to a voltage node to which the voltage VMIM is applied, and a second node connected to the second floating diffusion node FD2. For example, the first voltage V1 may be a constant voltage. The voltage VMIM may be a voltage that transitions between a high level and a low level. The high level may be equal to the first voltage V1. The low level may be lower than the first voltage V1, and lower than the ground voltage GND.

The fourth switch transistor SW4 may include a gate electrode connected to the fourth switch line SWL4, a first node connected to the first node of the capacitor C and the voltage node to which the voltage VMIM is applied, and a second node connected to the first voltage node to which the first voltage V1 is applied and the first node of the reset gate transistor RG.

For example, the size of the first photodiode PD1 may be greater than the size of the second photodiode PD2. Therefore, the number of electrons generated by the first photodiode PD1 may be greater than the number of electrons generated by the second photodiode PD2 in response to the same incident light.

In a process in which the pixel PXc converts the intensity of the incident light into the pixel voltage, first, the reset gate transistor RG and the dual conversion gain transistor DCG are turned on, and the first floating diffusion node FD1 may be initialized to a reset voltage. In an embodiment, the reset voltage may correspond to the first voltage V1. The present disclosure is not limited thereto. For example, the reset voltage may be set to a voltage different from the first voltage V1. Hereinafter, an embodiment in which the reset voltage is equal to the first voltage V1 is described. The first transfer gate transistor TG1 may dump electrons generated by the first photodiode PD1 into the first floating diffusion node FD1. With the electrons being dumped, the voltage of the first floating diffusion node FD1 may decrease from the first voltage V1. The source follower transistor SF may output the pixel voltage corresponding to a change in the voltage of the first floating diffusion node FD1 to the column line CL through the select gate transistor SG.

When the third switch transistor SW3 is turned on and the second transfer gate transistor TG2 is turned on, electrons accumulated in the second photodiode PD2 are emptied, and the second floating diffusion node FD2 may be reset to the first voltage V1.

When the second transfer gate transistor TG2 is turned on, electrons accumulated in the second photodiode PD2 may be dumped into the second floating diffusion node FD2. When the first switch transistor SW1 and the dual conversion gain transistor DCG are turned on, a change in the voltage of the second floating diffusion node FD2 may be transmitted to the first floating diffusion node FD1. The source follower transistor SF may output a pixel voltage corresponding to a change in the voltage of the second floating diffusion node FD2 to the column line CL through the select gate transistor SG.

In some example embodiment, the first floating diffusion node FD1 may be reset to the first voltage V1 before transferring the voltage of the second floating diffusion node FD2 to the first floating diffusion nodes FD1. For example, the first and second photodiodes PD1 and PD2 may generate electrons in response to light, the electrons generated by the first pixel diode PD1 may be transferred to the first diffusion node FD1 and may be sensed by the source follower transistor SF, and then the electrons generated by the second pixel diode PD2 may be transferred to the first diffusion node FD1 via the second diffusion node FD1 and may be sensed by the source follower transistor SF. Between the sensing of the electrons generated by the first pixel diode PD1 and the sensing of the electrons generated by the second pixel diode PD2, the first diffusion node FD1 may be reset to the first voltage V1.

In some example embodiment, in the time period in which the readout is performed, the reset operation RST and the signal sensing operation SIG of the first photodiode PD1 may be performed while the dual conversion gain transistor DCG is turned off, and the signal sensing operation SIG and the reset operation RSG of the first photo diode PD1 may be perform while the dual conversion gains transistor DCG is turn on. In addition, in the time period in which the readout is performed, the signal sensing operation SIG and the reset operation RST of the second photodiode PD2 may be performed while the dual conversion gain transistor DCG is turned on.

For example, during the time period in which the readout is not performed, the first switch transistor SW1 may be turned off, and the second switch transistor SW2 may be turned on. During the time period in which the readouts of the first photodiode PD1 and the second photodiode PD2 are sequentially performed, the first switch transistor SW1 may be turned on and the second switch transistor SW2 may be turned off.

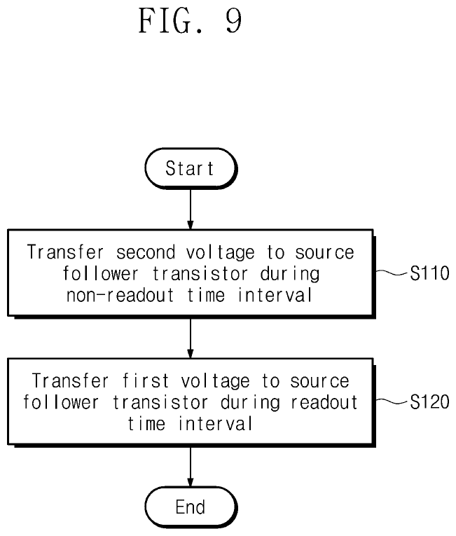

FIG. 9 illustrates a method of operating the image sensor 100 according to an embodiment of the present disclosure. Referring to FIG. 1, FIG. 2 (or FIG. 6, FIG. 7, or FIG. 8), and FIG. 9, in S110, during the non-readout time interval, the image sensor 100 may deliver (i.e., supply) the second voltage V2 to the source follower transistor (i.e., a first source/drain terminal of the source follower transistor). The second voltage V2 may be the positive voltage lower than the first voltage V1. The second voltage V2 may be lower than the voltage of the floating diffusion node FD, FD1, or FD2. The second voltage V2 allows electrons to be trapped in trap sites of the source follower transistor SF, thereby suppressing electrons from being trapped in trap sites of the source follower transistor SF by the first voltage V1 during the readout period. The trap sites of the source follower transistor SF may include defects at an interface between a gate oxide of the source follower transistor SF and a channel thereof, defects within the gate oxide, or defects within the channel.

In S120, during the readout time interval, the image sensor 100 may transmit the first voltage V1 to the source follower transistor. For example, the readout time may include the reset operation RST during which the voltage of the reset floating diffusion node FD, FD1, or FD2 is sensed and the signal sensing operation SIG during which the voltage of the floating diffusion node FD, FD1, or FD2 in which electrons generated by the photodiode PD, PD1, PD2, PD3, or PD4 are dumped is sensed.

If it is suppressed that a number of the electrons trapped in trap sites of the source follower transistor SF change in the readout time period, it may be prevented that the threshold voltage of the source follower transistor SF changes or the amount of current of the current source CS changes during the readout time period. Accordingly, the quality of the image data (for example, the digital signal DS) generated by the image sensor 100 is improved. In an embodiment, the non-readout time interval and the readout time interval are alternately repeated, and the second voltage and the first voltage are alternately supplied to the first source/drain terminal of the source follower transistor.

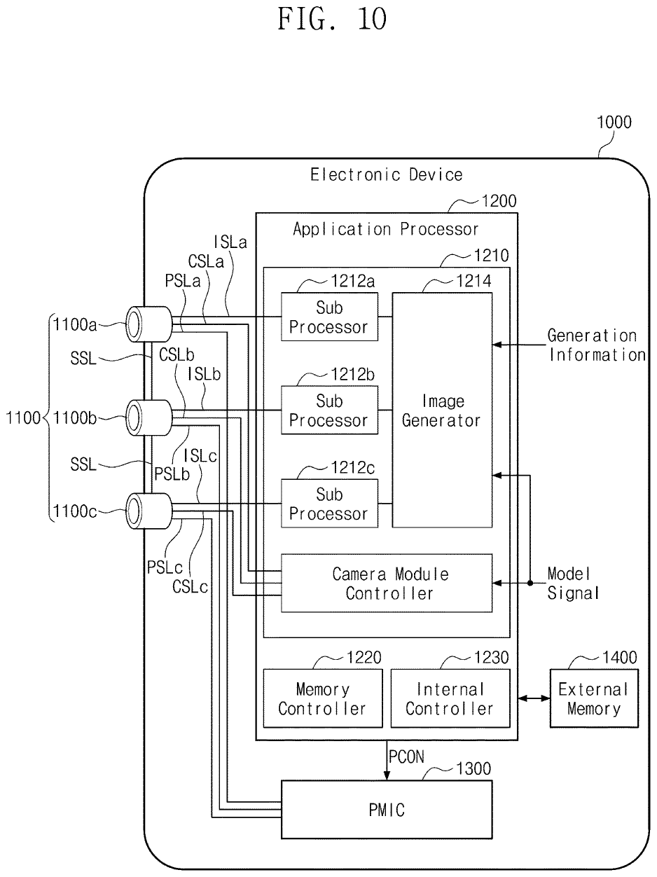

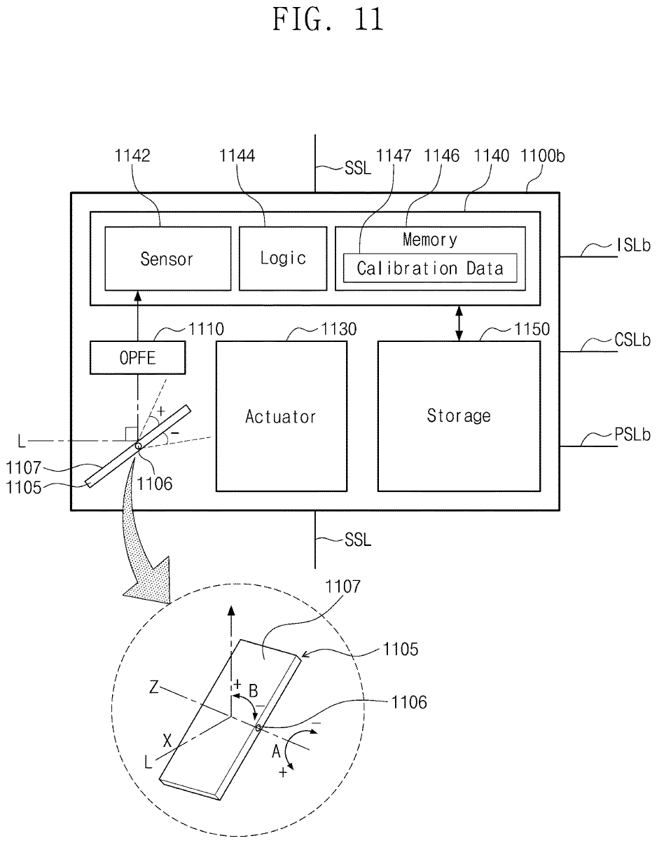

FIG. 10 is a block diagram of an electronic device including a multi-camera module. FIG. 11 is a block diagram illustrating a camera module of FIG. 10 in detail.

Referring to FIG. 10, an electronic device 1000 may include a camera module group 1100, an application processor 1200, a power management integrated circuit (PMIC) 1300, and an external memory 1400.

The camera module group 1100 may include a plurality of camera modules 1100a, 1100b, and 1100c. An electronic device including three camera modules 1100a, 1100b, and 1100c is illustrated in FIG. 10, but the present disclosure is not limited thereto. In some embodiments, the camera module group 1100 may include only two camera modules. Also, in some embodiments, the camera module group 1100 may include “j” camera modules (j being a natural number of 4 or more). For example, each of the plurality of camera modules 1100 a, 1100 b, and 1100c of the camera module group 1100 may include the image sensor 100 of FIG. 1.

Below, a detailed configuration of the camera module 1100b will be more fully described with reference to FIG. 11, but the following description may be equally applied to the remaining camera modules 1100a and 1100c.

Referring to FIG. 11, the camera module 1100b may include a prism 1105, an optical path folding element (OPFE) 1110, an actuator 1130, an image sensing device 1140, and storage 1150.

The prism 1105 may include a reflecting plane 1107 of a light reflecting material and may change a path of a light “L” incident from the outside.

In some embodiments, the prism 1105 may change a path of the light “L” incident in a first direction (X) to a second direction (Y) perpendicular to the first direction (X). Also, the prism 1105 may change the path of the light “L” incident in the first direction (X) to the second direction (Y) perpendicular to the first (X-axis) direction by rotating the reflecting plane 1107 of the light reflecting material in direction “A” about a central axis 1106 or rotating the central axis 1106 in direction “B”. In this case, the OPFE 1110 may move in a third direction (Z) perpendicular to the first direction (X) and the second direction (Y).

In some embodiments, as illustrated in FIG. 11, a maximum rotation angle of the prism 1105 in direction “A” may be equal to or smaller than 15 degrees in a positive A direction and may be greater than 15 degrees in a negative A direction, but the present disclosure is not limited thereto.

In some embodiments, the prism 1105 may move within approximately 20 degrees in a positive or negative B direction, between 10 degrees and 20 degrees, or between 15 degrees and 20 degrees; here, the prism 1105 may move at the same angle in the positive or negative B direction or may move at a similar angle within approximately 1 degree.

In some embodiments, the reflecting plane 1107 of the light reflecting material in the third direction (e.g., Z direction) may be moved parallel to a direction in which the central axis 1106 extends.

The OPFE 1110 may include optical lenses composed of “i” groups (i being a natural number), for example. Here, “i” lens may move in the second direction (Y) to change an optical zoom ratio of the camera module 1100b. For example, when a default optical zoom ratio of the camera module 1100b is “Z”, the optical zoom ratio of the camera module 1100b may be changed to an optical zoom ratio of 3Z, 5Z, or 5Z or more by moving “i” optical lens included in the OPFE 1110.

The actuator 1130 may move the OPFE 1110 or an optical lens (hereinafter referred to as an “optical lens”) to a specific location. For example, the actuator 1130 may adjust a location of an optical lens such that an image sensor 1142 is placed at a focal length of the optical lens for accurate sensing.

The image sensing device 1140 may include the image sensor 1142, control logic 1144, and a memory 1146. The image sensor 1142 may sense an image of a sensing target by using the light “L” provided through an optical lens.

The control logic 1144 may control overall operations of the camera module 1100b. For example, the control logic 1144 may control an operation of the camera module 1100b based on a control signal provided through a control signal line CSLb.

The memory 1146 may store information, which is necessary for an operation of the camera module 1100b, such as calibration data 1147. The calibration data 1147 may include information necessary for the camera module 1100b to generate image data by using the light “L” provided from the outside. The calibration data 1147 may include, for example, information about the degree of rotation described above, information about the focal length, information about an optical axis, etc. In the case where the camera module 1100b is implemented in the form of a multi-state camera in which a focal length varies depending on a location of an optical lens, the calibration data 1147 may include a focal length value for each location (or state) of the optical lens and information about auto focusing. The multi-state camera may be a type of multi-sensor camera that combines multiple imaging units to capture visual data from different perspectives.

The storage 1150 may store image data sensed through the image sensor 1142. The storage 1150 may be disposed outside the image sensing device 1140 and may be implemented in a manner where the storage 1150 and a sensor chip constituting the image sensing device 1140 are stacked. In some embodiments, the storage 1150 may be implemented with an electrically erasable programmable read only memory (EEPROM), but the present disclosure is not limited thereto.

Referring together to FIGS. 10 and 11, in some embodiments, each of the plurality of camera modules 1100a, 1100b, and 1100c may include the actuator 1130. As such, the same calibration data 1147 or different calibration data 1147 may be included in the plurality of camera modules 1100a, 1100b, and 1100c depending on operations of the actuators 1130 therein.

In some embodiments, one camera module (e.g., 1100b) among the plurality of camera modules 1100a, 1100b, and 1100c may be a folded lens shape of camera module in which the prism 1105 and the OPFE 1110 described above are included, and the remaining camera modules (e.g., 1100a and 1100c) may be a vertical shape of camera module in which the prism 1105 and the OPFE 1110 described above are omitted; however, the present disclosure is not limited thereto.

In some embodiments, one camera module (e.g., 1100c) among the plurality of camera modules 1100a, 1100b, and 1100c may be, for example, a vertical shape of depth camera extracting depth information by using an infrared ray (IR). In this case, the application processor 1200 may merge image data provided from the depth camera and image data provided from any other camera module (e.g., 1100a or 1100b) and may generate a three-dimensional (3D) depth image.

In some embodiments, at least two camera modules (e.g., 1100a and 1100b) among the plurality of camera modules 1100a, 1100b, and 1100c may have different fields of view. In this case, the at least two camera modules (e.g., 1100a and 1100b) among the plurality of camera modules 1100a, 1100b, and 1100c may include different optical lens, but the present disclosure is not limited thereto.

Also, in some embodiments, fields of view of the plurality of camera modules 1100a, 1100b, and 1100c may be different. In this case, the plurality of camera modules 1100a, 1100b, and 1100c may include different optical lens. The present disclosure is not limited thereto.

In some embodiments, the plurality of camera modules 1100a, 1100b, and 1100c may be disposed to be physically separated from each other. That is, the plurality of camera modules 1100a, 1100b, and 1100c may not use a sensing area of one image sensor 1142, but the plurality of camera modules 1100a, 1100b, and 1100c may include independent image sensors 1142 therein, respectively.

Returning to FIG. 10, the application processor 1200 may include an image processing device 1210, a memory controller 1220, and an internal memory 1230. The application processor 1200 may be implemented to be separated from the plurality of camera modules 1100a, 1100b, and 1100c. For example, the application processor 1200 and the plurality of camera modules 1100a, 1100b, and 1100c may be implemented with separate semiconductor chips.

The image processing device 1210 may include a plurality of sub-image processors 1212a, 1212b, and 1212c, an image generator 1214, and a camera module controller 1216.

The image processing device 1210 may include the plurality of sub-image processors 1212a, 1212b, and 1212c, the number of which corresponds to the number of the plurality of camera modules 1100a, 1100b, and 1100c.

Image data respectively generated from the camera modules 1100a, 1100b, and 1100c may be respectively provided to the corresponding sub-image processors 1212a, 1212b, and 1212c through separated image signal lines ISLa, ISLb, and ISLc. For example, the image data generated from the camera module 1100a may be provided to the sub-image processor 1212a through the image signal line ISLa, the image data generated from the camera module 1100b may be provided to the sub-image processor 1212b through the image signal line ISLb, and the image data generated from the camera module 1100c may be provided to the sub-image processor 1212c through the image signal line ISLc. This image data transmission may be performed, for example, by using a camera serial interface (CSI) based on the MIPI (Mobile Industry Processor Interface), but the present disclosure is not limited thereto.

Meanwhile, in some embodiments, one sub-image processor may be disposed to correspond to a plurality of camera modules. For example, the sub-image processor 1212a and the sub-image processor 1212c may be integrally implemented, not separated from each other as illustrated in FIG. 10; in this case, one of the pieces of image data respectively provided from the camera module 1100a and the camera module 1100c may be selected through a selection element (e.g., a multiplexer), and the selected image data may be provided to the integrated sub-image processor.

The image data respectively provided to the sub-image processors 1212a, 1212b, and 1212c may be provided to the image generator 1214. The image generator 1214 may generate an output image by using the image data respectively provided from the sub-image processors 1212a, 1212b, and 1212c, depending on image generating information Generation Information or a mode signal.

In detail, the image generator 1214 may generate the output image by merging at least a portion of the image data respectively generated from the camera modules 1100a, 1100b, and 1100c having different fields of view, depending on the image generating information Generation Information or the mode signal. Also, the image generator 1214 may generate the output image by selecting one of the image data respectively generated from the camera modules 1100a, 1100b, and 1100c having different fields of view, depending on the image generating information Generation Information or the mode signal.

In some embodiments, the image generating information Generation Information may include a zoom signal or a zoom factor. Also, in some embodiments, the mode signal may be, for example, a signal based on a mode selected from a user.

In the case where the image generating information Generation Information is the zoom signal (or zoom factor) and the camera modules 1100a, 1100b, and 1100c have different visual fields of view, the image generator 1214 may perform different operations depending on a kind of the zoom signal. For example, in the case where the zoom signal is a first signal, the image generator 1214 may merge the image data output from the camera module 1100a and the image data output from the camera module 1100c and may generate the output image by using the merged image signal and the image data output from the camera module 1100b that is not used in the merging operation. In the case where the zoom signal is a second signal different from the first signal, without the image data merging operation, the image generator 1214 may select one of the image data respectively output from the camera modules 1100a, 1100b, and 1100c and may output the selected image data as the output image. However, the present disclosure is not limited thereto, and a way to process image data may be modified without limitation if necessary.

In some embodiments, the image generator 1214 may generate merged image data having an increased dynamic range by receiving a plurality of image data of different exposure times from at least one of the plurality of sub-image processors 1212a, 1212b, and 1212c and performing high dynamic range (HDR) processing on the plurality of image data.

The camera module controller 1216 may provide control signals to the camera modules 1100a, 1100b, and 1100c, respectively. The control signals generated from the camera module controller 1216 may be respectively provided to the corresponding camera modules 1100a, 1100b, and 1100c through control signal lines CSLa, CSLb, and CSLc separated from each other.

One of the plurality of camera modules 1100a, 1100b, and 1100c may be designated as a master camera (e.g., 1100b) depending on the image generating information Generation Information including a zoom signal or the mode signal, and the remaining camera modules (e.g., 1100a and 1100c) may be designated as a slave camera. The above designation information may be included in the control signals, and the control signals including the designation information may be respectively provided to the corresponding camera modules 1100a, 1100b, and 1100c through the control signal lines CSLa, CSLb, and CSLc separated from each other.

Camera modules operating as a master and a slave may be changed depending on the zoom factor or an operating mode signal. For example, in the case where the field of view of the camera module 1100a is wider than the field of view of the camera module 1100b and the zoom factor indicates a low zoom ratio, the camera module 1100b may operate as a master, and the camera module 1100a may operate as a slave. In contrast, in the case where the zoom factor indicates a high zoom ratio, the camera module 1100a may operate as a master, and the camera module 1100b may operate as a slave.

In some embodiments, the control signal provided from the camera module controller 1216 to each of the camera modules 1100a, 1100b, and 1100c may include a synchronization enable signal. For example, in the case where the camera module 1100b is used as a master camera and the camera modules 1100a and 1100c are used as a slave camera, the camera module controller 1216 may transmit the synchronization enable signal to the camera module 1100b. The camera module 1100b that is provided with the synchronization enable signal may generate a synchronization signal based on the provided synchronization enable signal and may provide the generated synchronization signal to the camera modules 1100a and 1100c through a synchronization signal line SSL. The camera module 1100b and the camera modules 1100a and 1100c may be synchronized with the synchronization signal to transmit image data to the application processor 1200.

In some embodiments, the control signal provided from the camera module controller 1216 to each of the camera modules 1100a, 1100b, and 1100c may include mode information according to the mode signal. Based on the mode information, the plurality of camera modules 1100a, 1100b, and 1100c may operate in a first operating mode and a second operating mode with regard to a sensing speed.

In the first operating mode, the plurality of camera modules 1100a, 1100b, and 1100c may generate image signals at a first speed (e.g., may generate image signals of a first frame rate), may encode the image signals at a second speed (e.g., may encode the image signal of a second frame rate higher than the first frame rate), and transmit the encoded image signals to the application processor 1200. In this case, the second speed may be 30 times or less the first speed.

The application processor 1200 may store the received image signals, that is, the encoded image signals in the internal memory 1230 provided therein or the external memory 1400 placed outside the application processor 1200. Afterwards, the application processor 1200 may read and decode the encoded image signals from the internal memory 1230 or the external memory 1400 and may display image data generated based on the decoded image signals. For example, the corresponding one among the sub-image processors 1212a, 1212b, and 1212c of the image processing device 1210 may perform decoding and may also perform image processing on the decoded image signal.

In the second operating mode, the plurality of camera modules 1100a, 1100b, and 1100c may generate image signals at a third speed (e.g., may generate image signals of a third frame rate lower than the first frame rate) and transmit the image signals to the application processor 1200. The image signals provided to the application processor 1200 may be signals that are not encoded. The application processor 1200 may perform image processing on the received image signals or may store the image signals in the internal memory 1230 or the external memory 1400.

The PMIC 1300 may supply powers, for example, power supply voltages to the plurality of camera modules 1100a, 1100b, and 1100c, respectively. For example, under control of the application processor 1200, the PMIC 1300 may supply a first power to the camera module 1100a through a power signal line PSLa, may supply a second power to the camera module 1100b through a power signal line PSLb, and may supply a third power to the camera module 1100c through a power signal line PSLc.

In response to a power control signal PCON from the application processor 1200, the PMIC 1300 may generate a power corresponding to each of the plurality of camera modules 1100a, 1100b, and 1100c and may adjust a level of the power. The power control signal PCON may include a power adjustment signal for each operating mode of the plurality of camera modules 1100a, 1100b, and 1100c. For example, the operating mode may include a low-power mode. In this case, the power control signal PCON may include information about a camera module operating in the low-power mode and a set power level. Levels of the powers respectively provided to the plurality of camera modules 1100a, 1100b, and 1100c may be identical to each other or may be different from each other. Also, a level of a power may be dynamically changed.

In some example embodiment, the image sensor 100 described with reference to FIGS. 1 to 9 may correspond to the image sensor 1142 of FIG. 11. In the image sensor 1142, the first voltage V1 may be supplied to the first source/drain terminal of the source follower transistor SF of each pixel of the pixels PX, PXa, PXb, and PXc during the readout time, and the second voltage V2 may be supplied to the first source/drain terminal of the source follower transistor SF of each pixel of the pixels PX, PXa, PXB, and PXC during the non-readout time. In an embodiment, the second voltage V2 and the first voltage V1 may be alternately supplied to the first source/drain terminal of the source follower transistor SF of each pixel of the pixels PX, PXa, PXB, and PXC. For example, during the non-readout time, the second voltage V2 may be supplied to the first source/drain terminal of the source follower transistor SF of each pixel of the pixels PX, PXa, PXB, and PXC, and during the readout time, the first voltage V1 may be supplied to the first source/drain terminal of the source follower transistor SF of each pixel of the pixels PX, PXa, PXB, and PXC.

The second voltage V2 may be the positive voltage lower than the first voltage V1. The second voltage V2 may be lower than the voltage of the floating diffusion node FD, FD1, or FD2 of each pixel PX, PXa, PXb, or PXc. The second voltage V2 may cause electrons to be trapped in trap sites of the source follower transistor SF during the non-readout time, thereby inhibiting the trapped electrons being vary by the first voltage V1 and the current source CS during the readout time. For example, the second voltage V2 may cause electrons to be trapped in the trap sites of the source follower transistor SF during the non-readout time, thereby preventing the first voltage V1 and a driving current of the current source CS (i.e., an output signal of a pixel) from varying due to trapping of the trap sites in the source follower transistor SF during the readout time.

If variation of trapped electrons in the source follower transistor SF during the readout time is suppressed, the threshold voltage of the source follower transistor SF may be kept constant, and the amount of current of the current source CS may be kept constant. For example, if the trapping of electrons in the source follower transistor SF during the readout time is suppressed, the threshold voltage of the source follower transistor SF and the amount of the driving current of the current source CS may be kept constant. Accordingly, the quality of raw image data generated by the image sensor 1142 may be improved.

In the above embodiments, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve any order or a numerical meaning of any form.

In the above embodiments, components according to embodiments of the present disclosure are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP). The IP may be a reusable library of pre-designed circuits or logic blocks which can be integrated into larger integrated circuit.

According to embodiments of the present disclosure, electrons are kept trapped in some transistors during a readout time. Therefore, in the readout time, a signal difference of an output signal may be avoided due to trapping of electrons. An image sensor that corrects noises and distortions generated by electrons trapped in the transistor, an operation method of the image sensor, and a camera module including the image sensor are provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method of operating an image sensor, the method comprising:
alternately supplying a first voltage and a second voltage to a first source/drain terminal of a source-follower transistor,
wherein a gate electrode of the source-follower transistor is connected to a first floating diffusion node, and
wherein the alternately supplying of the first voltage and the second voltage includes:
supplying the second voltage to the first source/drain terminal of the source-follower transistor;
resetting the first floating diffusion node to a reset voltage;
blocking the supplying of the second voltage and supplying the first voltage to the first source/drain terminal of the source-follower transistor;
transmitting a first signal of a first photodiode to the first floating diffusion node;
sensing a first signal of the first floating diffusion node through the source-follower transistor; and
blocking the supplying of the first voltage to the first source/drain terminal of the source-follower transistor and supplying the second voltage to the first source/drain terminal of the source-follower transistor.

2. The method of claim 1,
wherein the second voltage is lower than the first voltage.

3. The method of claim 1,
wherein the first voltage and the second voltage are positive voltages.

4. The method of claim 1,
wherein the second voltage is lower than the reset voltage of the first floating diffusion node, and
wherein the reset voltage of the first floating diffusion node is equal to the first voltage.

5. The method of claim 1,
wherein the supplying of the second voltage to the first source/drain terminal of the source-follower transistor coupled to the first floating diffusion node comprises trapping electrons in trap sites of the source-follower transistor using the second voltage.

6. The method of claim 5,
wherein the electrons trapped in the source-follower transistor prevent other electrons from being trapped in the source-follower transistor during a time when the first voltage is supplied to the first source/drain terminal of the source-follower transistor.

7. The method of claim 1, further comprising:
increasing a capacitance of the first floating diffusion node; and
sensing a second signal of the first floating diffusion node having the increased capacitance through the source-follower transistor,
wherein the first voltage is supplied to the first source/drain terminal of the source-follower transistor during the transmitting of the first signal of the first photodiode to the first floating diffusion node, the sensing of the first signal of the first floating diffusion node through the source-follower transistor, the increasing of the capacitance of the first floating diffusion node, and the sensing of the second signal of the first floating diffusion node having the increased capacitance through the source-follower transistor.

8. The method of claim 7, further comprising:
resetting the first floating diffusion node storing electrons corresponding to the second signal to the reset voltage; and
sensing a third signal of the first floating diffusion node having the reset voltage through the source-follower transistor,
wherein the first voltage is supplied to the first source/drain terminal of the source-follower transistor during the transmitting of the first signal of the first photodiode to the first floating diffusion node, the sensing of the first signal of the first floating diffusion node through the source-follower transistor, the increasing of the capacitance of the first floating diffusion node, the sensing of the second signal of the first floating diffusion node having the increased capacitance through the source-follower transistor, the resetting of the first floating diffusion node storing electrons corresponding to the second signal to the reset voltage, and the sensing of the third signal of the first floating diffusion node having the reset voltage through the source-follower transistor.

9. The method of claim 1,
wherein the image sensor further comprises a plurality of photodiodes,
wherein the method further comprises transmitting signals of the plurality of photodiodes to the first floating diffusion node,
wherein electrons generated by the first photodiode and the plurality of photodiodes are stored in the first floating diffusion node as an accumulated first signal of the first floating diffusion node, and
wherein the sensing of the first signal is performed by sensing the accumulated first signal of the first floating diffusion node.

10. The method of claim 9, further comprising:
increasing a capacitance of the first floating diffusion node; and
sensing a second signal of the first floating diffusion node having the increased capacitance through the source-follower transistor,
wherein the first voltage is supplied to the source-follower transistor during the transmitting of the first signal of the first photodiode and the signals of the plurality of photodiodes to the first floating diffusion node, the sensing of the accumulated first signal of the first floating diffusion node through the source-follower transistor, the increasing of the capacitance of the first floating diffusion node, and the sensing of the second signal of the first floating diffusion node having the increased capacitance through the source-follower transistor.

11. The method of claim 1,
wherein the image sensor further comprises a second photodiode,
wherein the method further comprises:
transmitting a second signal of the second photodiode to the first floating diffusion node; and
sensing a second signal of the first floating diffusion node through the source-follower transistor, and
wherein the source-follower transistor is supplied with the first voltage during the transmitting of the first signal of the first photodiode to the first floating diffusion node, the transmitting of the second signal of the second photodiode to the first floating diffusion node, the sensing of the first signal of the first floating diffusion node through the source-follower transistor, and the sensing of the second signal of the first floating diffusion node through the source-follower transistor.

12. The method of claim 11, further comprising:
resetting the first floating diffusion node having the first signal to the reset voltage,
wherein the resetting of the first floating diffusion node is performed between the sensing of the first signal of the first floating diffusion node and the transmitting of the second signal of the second photodiode to the first floating diffusion node.

13. The method of claim 1,
wherein the image sensor further comprises a second photodiode and a second floating diffusion node selectively connected to the second photodiode,
wherein the method further comprises:
resetting the first floating diffusion node and the second floating diffusion node to the reset voltage;
transmitting a second signal of the second photodiode to the second floating diffusion node;
transmitting a second signal of the second floating diffusion node to the first floating diffusion node so that the first floating diffusion node has a transferred second signal; and
sensing the transferred second signal of the first floating diffusion node through the source-follower transistor, and
wherein the source-follower transistor is supplied with the first voltage during the transmitting of the first signal of the first photodiode to the first floating diffusion node, the sensing of the first signal of the first floating diffusion node through the source-follower transistor, the resetting of the first floating diffusion node and the second floating diffusion node to the reset voltage, the transmitting of the second signal of the second photodiode to the second floating diffusion node, the transmitting of the second signal of the second floating diffusion node to the first floating diffusion node, and the sensing of the transferred second signal of the first floating diffusion node through the source-follower transistor.

14. A method of operating an image sensor, the method comprising:
turning off a select-gate transistor connecting a source-follower transistor to a current source, wherein the source-follower transistor is connected to a floating diffusion node;
during a time when the select-gate transistor is turned off, trapping electrons in trap sites of the source-follower transistor, and resetting the floating diffusion node to a reset voltage;
turning on the select-gate transistor; and
during a time when the select-gate transistor is turned on, transmitting a signal of a photodiode to the floating diffusion node, and sensing a signal of the floating diffusion node through the source-follower transistor.

15. The method of claim 14,
wherein the turning off of the select-gate transistor and the turning on of the select-gate transistor are alternately performed.

16. The method of claim 14, further comprising:
supplying a second voltage to a first source/drain terminal of the source-follower transistor during the time when the select-gate transistor is turned off.

17. The method of claim 16, further comprising:
supplying a first voltage to the first source/drain terminal of the source-follower transistor during the time when the select-gate transistor is turned on.

18. The method of claim 17,
wherein the second voltage is lower than the first voltage.

19. The method of claim 17,
wherein the second voltage is lower than the reset voltage of the floating diffusion node, and
wherein the reset voltage is equal to the first voltage.

20. An image sensor comprising:
a photodiode;
a transfer gate transistor connected between the photodiode and a floating diffusion node;
a source-follower transistor including a first source/drain terminal, a second source/drain terminal, and a gate electrode coupled to the floating diffusion node;
a first switch transistor selectively connecting the first source/drain terminal of the source-follower transistor to a first voltage node supplying a first voltage;
a second switch transistor selectively connecting the first source/drain terminal of the source-follower transistor to a second voltage node supplying a second voltage; and
a select-gate transistor selectively connecting the second source/drain terminal of the source-follower transistor to a current source,
wherein during a non-readout time period in which the select-gate transistor is turned off, the first switch transistor is turned off, and the second switch transistor is turned on to supply the second voltage to a first/source drain terminal of the source-follower transistor and trap electrons in trap sites of the source-follower transistor using the second voltage, and
wherein during a readout time period in which the select-gate transistor is turned on, the second switch transistor is turned off, and the first switch transistor is turned on to supply the first voltage to the first/source drain terminal of the source-follower transistor for sensing a signal of the floating diffusion node.
